(19) United States
(12) Patent Application Publication
(10) Pub. No.: US 2026/0156998 A1
(43) Pub. Date: Jun. 4, 2026

(54) DISPLAY DEVICE AND ELECTRONIC DEVICE

(71) Applicant: Samsung Display Co., LTD., Yongin-si (KR)

(72) Inventor: Jin Hyuk JANG, Yongin-si (KR)

(73) Assignee: Samsung Display Co., LTD., Yongin-si (KR)

(21) Appl. No.: 19/316,226

(22) Filed: Sep. 2, 2025

(30) Foreign Application Priority Data
Dec. 3, 2024 (KR) 10-2024-0177737

(51) Int. Cl. H10H 29/39; G02B 27/01; H10H 29/49

(52) U.S. Cl. CPC H10H 29/39; H10H 29/49; G02B 27/0172

(57) ABSTRACT

A display device includes a backplane including a first backplane layer including a first substrate and a switching transistor disposed on the first substrate, and a second backplane layer including a second substrate and a driving transistor disposed on the second substrate, and a light emitting element layer disposed on the backplane and including a light emitting element electrically connected to the driving transistor.

### CROSS-REFERENCE TO RELATED APPLICATION

This application claims priority to and the benefits of Korean Patent Application No.

10-2024-0177737 under 35 U.S.C. § 119, filed on Dec. 3, 2024, in the Korean Intellectual Property Office, the entire contents of which are incorporated herein by reference.

### BACKGROUND

### 1. Technical Field

Embodiments relate to a display device and an electronic device.

### 2. Description of the Related Art

As the information society develops, the demand for display devices for displaying images has increased and diversified. Accordingly, various types of display devices including light emitting display devices have been developed. The light emitting display device may include a backplane including pixel circuits and a light emitting element layer including light emitting elements.

### SUMMARY

Aspects of the disclosure provide a display device and an electronic device capable of reducing power consumption.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including, a backplane including a first backplane layer including: a first substrate and a switching transistor disposed on the first substrate, and a second backplane layer including a second substrate and a driving transistor disposed on the second substrate, and a light emitting element layer disposed on the backplane and including a light emitting element electrically connected to the driving transistor.

In an embodiment, the switching transistor may be a thin film transistor formed on the first substrate, and the driving transistor may be a metal oxide semiconductor field effect transistor formed on the second substrate.

In an embodiment, the first substrate and the second substrate may be made of different materials.

In an embodiment, the first substrate may be an insulating substrate, and the second substrate may be a semiconductor substrate.

In an embodiment, the first backplane layer may further include a capacitor disposed on the first substrate.

In an embodiment, the first backplane layer may further include a connection electrode disposed on the first substrate and electrically connected to the switching transistor, and the connection electrode may be exposed on an upper surface of the first backplane layer.

In an embodiment, the second backplane layer may further include a first contact terminal and a second contact terminal disposed on the second substrate and electrically connected to a source region and a drain region of the driving transistor, respectively.

In an embodiment, the second backplane layer may be disposed on the first backplane layer, and the light emitting element layer may be disposed on the second backplane layer.

In an embodiment, one of the first contact terminal and the second contact terminal may be electrically connected to the connection electrode, and the other of the first contact terminal and the second contact terminal may be electrically connected to the light emitting element.

In an embodiment, the backplane may further include a line layer disposed between the second backplane layer and the light emitting element layer, and the line layer may include conductive patterns electrically connecting the driving transistor to the light emitting element and the switching transistor.

In an embodiment, the light emitting element layer may further include a pixel electrode disposed on the backplane and electrically connected to the driving transistor, and the light emitting element may be disposed on the pixel electrode.

In an embodiment, the light emitting element may be connected to the pixel electrode.

In an embodiment, the light emitting element may be a micro light emitting diode including a first semiconductor layer, a light emitting layer, and a second semiconductor layer that are sequentially disposed on the pixel electrode.

In an embodiment, the display device may further include a pixel including the switching transistor, the driving transistor, and the light emitting element, wherein the light emitting element layer may further include a common electrode disposed on the light emitting element.

According to an aspect of the disclosure, there is provided a display device including, a first backplane layer including an insulating substrate and a thin film transistor formed on the insulating substrate, a second backplane layer disposed on the first backplane layer and including a semiconductor substrate and a metal oxide semiconductor field effect transistor formed on the semiconductor substrate, and a light emitting element layer disposed on the second backplane layer and including a light emitting element.

In an embodiment, the first backplane layer may further include a connection electrode electrically connected between the thin film transistor and the metal oxide semiconductor field effect transistor.

In an embodiment, the display device may further include a line layer disposed between the second backplane layer and the light emitting element layer, and the line layer may include a conductive pattern electrically connected between the metal oxide semiconductor field effect transistor and the light emitting element.

In an embodiment, the light emitting element layer may further include a pixel electrode disposed on the line layer, and the light emitting element may be disposed on the pixel electrode.

In an embodiment, display device may further include a pixel including the thin film transistor, the metal oxide semiconductor field effect transistor, and the light emitting element, the thin film transistor may be a switching transistor of the pixel, and the metal oxide semiconductor field effect transistor may be a driving transistor of the pixel.

According to an aspect of the disclosure, there is provided an electronic device including a display module including a display panel, and a processor that transmits an image data signal to the display module. The display panel may include a backplane including a first backplane layer including a first substrate and a switching transistor disposed on the first substrate, and a second backplane layer including a second substrate and a driving transistor disposed on the second substrate, and a light emitting element layer disposed on the backplane and including a light emitting element electrically connected to the driving transistor.

A display device according to embodiments may include a backplane including a first backplane layer including a switching transistor and a second backplane layer including a driving transistor. In some embodiments, the switching transistor may be a thin film transistor, and the driving transistor may be a metal oxide semiconductor field effect transistor.

According to embodiments, by forming the switching transistor and the driving transistor separately in the first backplane layer and the second backplane layer, respectively, it is possible to reduce a degree of integration of the backplane and readily manufacture a high-resolution display device. In addition, by forming the driving transistor as the metal oxide semiconductor field effect transistor, it is possible to reduce power consumption of the display device.

However, effects according to the embodiments of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to an embodiment;

FIG. 2 is a schematic view illustrating a pixel of the display device according to an embodiment;

FIG. 3 is a schematic plan view illustrating a display area of the display device according to an embodiment;

FIG. 4 is a schematic cross-sectional view illustrating a display panel of the display device according to an embodiment;

FIG. 5 is a schematic cross-sectional view illustrating a display area of the display device according to an embodiment;

FIG. 6 is a schematic cross-sectional view illustrating a pixel of the display device according to an embodiment;

FIG. 7 is a schematic view illustrating a smart watch including the display device according to an embodiment;

FIGS. 8 and 9 are schematic views illustrating a head mounted display device including the display device according to an embodiment;

FIG. 10 is a schematic view illustrating a head mounted display device including the display device according to an embodiment;

FIG. 11 is a schematic view illustrating an instrument board and a center fascia of a vehicle including the display devices according to an embodiment; and

FIG. 12 is a schematic view illustrating a transparent display device including the display device according to an embodiment.

FIG. 13 is a block diagram of an electronic device according to one embodiment of the disclosure.

### DETAILED DESCRIPTION OF THE EMBODIMENTS

The invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

Specific embodiments will be described below with reference to the attached drawings.

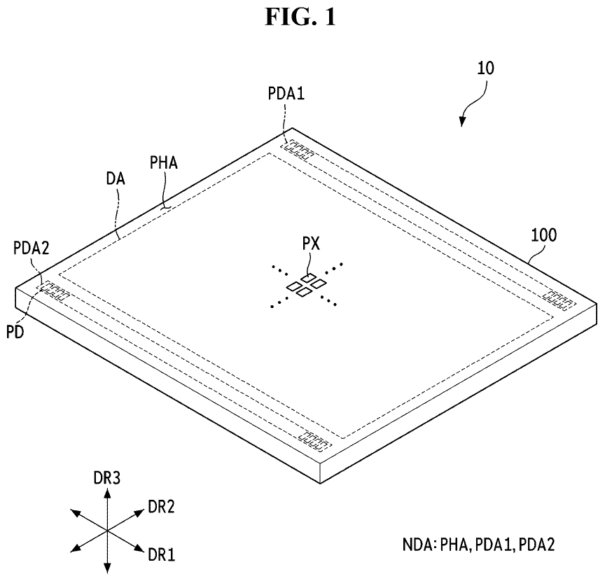

FIG. 1 is a schematic perspective view illustrating a display device according to an embodiment.

Referring to FIG. 1, a display device 10 may be a device that displays a moving image or a still image, and may be used as a display screen of various electronic devices. For example, the display device 10 may be included in various electronic devices such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs) and used as a display screen of the electronic devices. For example, the display device 10 may also be included in other electronic devices such as a virtual reality (VR) device or an augmented reality (AR) device.

In an embodiment, the display device 10 may be a light emitting display device including light emitting elements. For example, the display device 10 may be an organic light emitting display device including organic light emitting diodes, a quantum dot light emitting display device including quantum dot light emitting layers, an inorganic light emitting display device including inorganic semiconductors, or a micro light emitting display device including micro light emitting diodes such as micro light emitting diodes (micro LEDs) or nano light emitting diodes (nano LEDs).

Hereinafter, embodiments in which the display device 10 is a light emitting display device including micro light emitting diodes (micro LEDs) or nano light emitting diodes (nano LEDs) will be described. However, the display device 10 according to embodiments is not limited to the light emitting display device, and technical features of embodiments to be described below may be applied to other types of display devices.

The display device 10 may include a display panel 100 including a display area DA and a non-display area NDA. In an embodiment, the display panel 100 may have a quadrangular shape in plan view, but embodiments are not limited thereto. For example, the display panel 100 may also have other polygonal shapes other than the quadrangular shape, a circular shape, an elliptical shape, or an irregular shape in plan view.

In FIG. 1, a first direction DR1, a second direction DR2, and a third direction DR3 are denoted. In an embodiment, the first direction DR1, the second direction DR2, and the third direction DR3 may be a transverse direction, a longitudinal direction, and a thickness direction of the display panel 100, respectively.

The display area DA may be an area where pixels PX are disposed, and may be an area where an image is displayed by the pixels PX. For example, the pixels PX and lines (or portions of the lines) connected to the pixels PX may be disposed in the display area DA. In describing embodiments, the term “connection” may include the meaning of an electrical connection and/or a physical connection. An embodiment in which the display area DA has a quadrangular shape in plan view has been illustrated in FIG. 1, but a shape of the display area DA is not limited thereto.

Each of the pixels PX may emit light of a specific color. As an example, each of the pixels PX may emit red light, green light, blue light, white light, or light of another color.

In an embodiment, each of the pixels PX may include a light emitting element. For example, each pixel PX may include a light emitting element that emits red light, green light, blue light, white light, or light of another color.

In an embodiment, each of the pixels PX may include a light emitting element emitting light of a color coinciding with a light emitting color of the corresponding pixel PX. In another embodiment, at least one pixel PX may include a light emitting element emitting light of a color different from a light emitting color of the corresponding pixel PX, and a color filter or a light conversion layer corresponding to the light emitting color of the corresponding pixel PX may be disposed on the light emitting element.

In an embodiment, the light emitting element of each of the pixels PX may be a light emitting diode (LED). As an example, each of the pixels PX may include a micro LED or nano LED having a size in units of micrometers to nanometers. As an example, the light emitting element may be a micro LED having a transverse length, a longitudinal length, a diameter, or a height of several hundred micrometers, e.g., about 100 μm or less, but embodiments are not limited thereto. The light emitting element may emit light having a peak wavelength of a specific wavelength band. As an example, the light emitting element may emit light having a peak wavelength of a red wavelength band, a green wavelength band, or a blue wavelength band.

In an embodiment, each pixel PX may further include a pixel circuit electrically connected to the light emitting element. Each pixel circuit may supply a driving current to the light emitting element in response to driving signals supplied to the corresponding pixel PX. The pixel circuit may include circuit elements including a transistor.

The non-display area NDA may be an area other than the display area DA, and an image may be an area where an image is not displayed. The non-display area NDA may be disposed around the display area DA. As an example, the non-display area NDA may be disposed at an edge portion of the display panel 100 to surround the display area DA.

In an embodiment, the non-display area NDA may include a first pad area PDA1, a second pad area PDA2, and a peripheral area PHA. Lines connected to the pixels PX (e.g., portions of lines extending from the display area DA to the non-display area NDA) and pads PD may be disposed in the non-display area NDA.

An embodiment in which the display device 10 includes the first pad area PDA1 and the second pad area PDA2 respectively disposed on different sides (e.g., an upper side and a lower side) of the display area DA has been illustrated in FIG. 1, but the number or positions of pad areas PDA1 and PDA2 are not limited thereto. As an example, the display device 10 may also include only one of the first pad area PDA1 and the second pad area PDA2 or include three or more pad areas.

Each of the first pad area PDA1 and the second pad area PDA2 may include pads PD connected to an external circuit board. Driving signals and driving voltages for driving the pixels PX may be supplied from the external circuit board to the display device 10 through the pads PD.

The peripheral area PHA may be the remaining area of the non-display area NDA excluding the first pad area PDA1 and the second pad area PDA2. The peripheral area PHA may surround the display area DA. Lines connected between a display driver and/or the pads PD and the pixels PX (e.g., signal lines and power lines transferring the respective driving signals and driving voltages to the pixels PX) may pass through the peripheral area PHA.

In an embodiment, the peripheral area PHA may include a common voltage supply area. As an example, a common electrode disposed in the display area DA may extend to the peripheral area PHA, and may be connected to a power line transferring a common voltage (e.g., a second driving voltage supplied to the pixels PX) in the peripheral area PHA.

The peripheral area PHA may or may not include a driving circuit area. For example, the peripheral area PHA may further include a driving circuit area where at least a portion of the display driver electrically connected to the pixels PX is disposed, but embodiments are not limited thereto. As an example, each of a gate driver and a data driver including a scan driver may be disposed in the peripheral area PHA of the display panel 100 and electrically connected to the pixels PX through lines of the display panel 100 or may be disposed on a circuit board or the like outside the display panel 100 and electrically connected to the pixels PX through the pads PD and the line of the display panel 100.

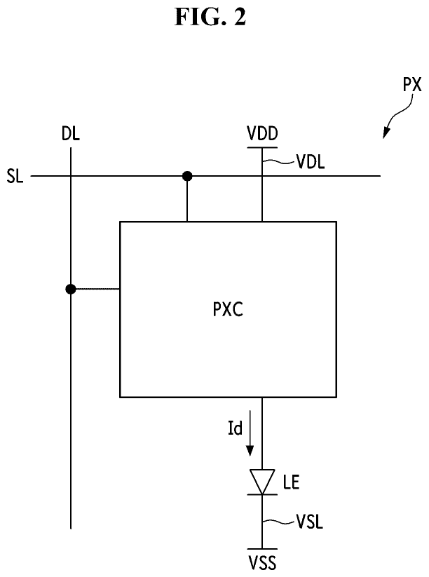

FIG. 2 is a schematic view illustrating a pixel of the display device according to an embodiment. For example, a configuration of the pixel PX that is included in the display device 10 of FIG. 1 is schematically illustrated in FIG. 2.

An embodiment in which the display device 10 is a light emitting display device and, accordingly, the pixel PX includes a light emitting element LE is illustrated in FIG. 2. However, embodiments are not limited thereto, and types and structures of the display device 10 and the pixel PX included in the display device 10 may be variously changed according to embodiments.

Referring to FIG. 2, the pixel PX may include a pixel circuit PXC and a light emitting element LE. A structure in which the pixel circuit PXC is connected between a first power line VDL and the light emitting element LE has been illustrated in FIG. 2, but embodiments are not limited thereto. For example, the pixel circuit PXC may also be connected between the light emitting element LE and a second power line VSL.

The pixel PX may include the pixel circuit PXC having various structures or shapes. Accordingly, the pixel circuit PXC has been briefly illustrated in the shape of a block in FIG. 2. In FIG. 2, a scan line SL transferring a scan signal, a data line DL transferring a data signal, the first power line VDL transferring a first driving voltage VDD (e.g., a high-potential pixel voltage or anode voltage), and the second power line VSL transferring a second driving voltage VSS (e.g., a low-potential common voltage or cathode voltage) have been illustrated as examples of signal lines and power lines that are connected to the pixel PX in FIG. 2, but embodiments are not limited thereto. For example, types, the numbers, or the like, of signal lines and/or power lines that are connected to each pixel PX may be variously changed according to a configuration or the like of the pixel circuit PXC.

The pixel circuit PXC may supply a driving current Id to the light emitting element LE in response to driving signals (e.g., the scan signal and the data signal, etc.) supplied to the pixel PX through the respective signal lines (e.g., the scan line SL and the data line DL, etc.). The pixel circuit PXC may include circuit elements including a driving transistor. For example, the pixel circuit PXC may include a driving transistor electrically connected between the first power line VDL and the light emitting element LE and supplying the driving current Id to the light emitting element LE, at least one capacitor including a storage capacitor storing a voltage corresponding to the data signal, and at least one switching transistor electrically connected to the driving transistor and the storage capacitor. In an embodiment, the pixel circuit PXC may include a compensation circuit for compensating for a characteristic deviation between the pixels PX, and accordingly, the pixel circuit PXC may include switching transistors.

The light emitting element LE may be connected between the pixel circuit PXC and the second power line VSL. The light emitting element LE may emit light in response to the driving current Id supplied from the pixel circuit PXC. For example, the light emitting element LE may emit light with luminance corresponding to a magnitude of the driving current during a period in which the driving current Id is supplied from the pixel circuit PXC.

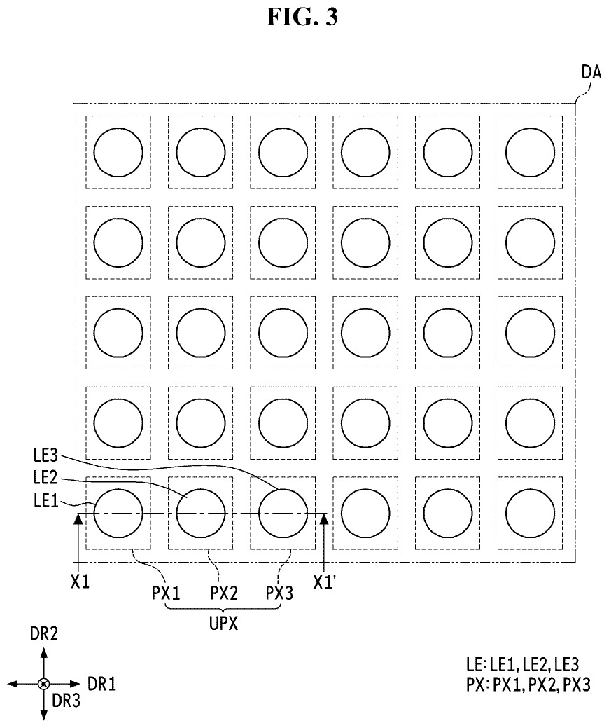

FIG. 3 is a schematic plan view illustrating a display area of the display device according to an embodiment. For example, FIG. 3 illustrates a schematic shape of pixels PX that are disposed in a portion of the display area DA of FIG. 1.

Referring to FIGS. 1 to 3, the display panel 100 of the display device 10 may include pixels PX disposed in the display area DA. The pixels PX may be arranged in the display area DA in a stripe shape or other shapes. Arrangement shapes, positions, sizes, and the like, of the pixels PX may be variously changed according to embodiments.

Each of the pixels PX may have a quadrangular shape such as a rectangular shape, a square shape, or a rhombic shape in plan view, but embodiments are not limited thereto. For example, each of the pixels PX may have other polygonal shapes other than the quadrangular shape, a circular shape, an elliptical shape, or other shapes in plan view.

In an embodiment, the pixels PX may include first pixels PX1 (e.g., red sub-pixels) emitting light of a first color (e.g., red light), second pixels PX2 (e.g., green sub-pixels) emitting light of a second color (e.g., green light), and third pixels PX3 (e.g., blue sub-pixels) emitting light of a third color (e.g., blue light). At least one first pixel PX1, at least one second pixel PX2, and at least one third pixel PX3 adjacent to each other may form each unit pixel UPX. As an example, one first pixel PX1, one second pixel PX2, and one third pixel PX3 sequentially disposed along the first direction DR1 may form a unit pixel UPX. The number, types arrangement structures, and the like, of pixels PX forming each unit pixel UPX may also be variously changed according to embodiments.

Each pixel PX may include each light emitting element LE. For example, the first pixel PX1 may include a first light emitting element LE1, the second pixel PX2 may include a second light emitting element LE2, and the third pixel PX3 may include a third light emitting element LE3. In an embodiment, the first light emitting element LE1, the second light emitting element LE2, and the third light emitting element LE3 may emit the light of the first color, the light of the second color, and the light of the third color, respectively. As an example, the first light emitting element LE1, the second light emitting element LE2, and the third light emitting element LE3 may emit the red light, the green light, and the blue light, respectively. In another embodiment, the first light emitting element LE1, the second light emitting element LE2, and the third light emitting element LE3 may emit light of the same color (e.g., blue light or white light), and light conversion patterns (e.g., wavelength conversion patterns including quantum dots) and/or color filters for converting or controlling a color or a wavelength of light emitted from each light emitting element LE may be disposed above at least one of the first light emitting element LE1, the second light emitting element LE2, and the third light emitting element LE3.

Each light emitting element LE may have a circular shape in plan view, but embodiments are not limited thereto. For example, each light emitting element LE may have a quadrangular shape (e.g., a rectangular shape, a square shape, or a rhombic shape), an elliptical shape, or other shapes in plan view.

An embodiment in which each pixel PX includes one light emitting element LE has been illustrated in FIG. 3, but embodiments are not limited thereto. For example, at least one of the first pixel PX1, the second pixel PX2, and the third pixel PX3 may also include light emitting elements LE.

For example, only the light emitting element LE among components of the pixel PX has been illustrated in FIG. 3, but the pixel PX may further include an additional component. For example, the pixel PX may further include the pixel circuit PXC as illustrated in FIG. 2.

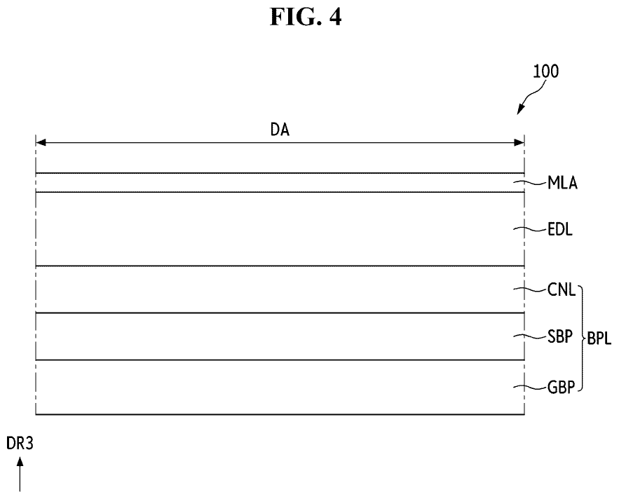

FIG. 4 is a schematic cross-sectional view illustrating a display panel of the display device according to an embodiment. For example, FIG. 4 schematically illustrates a cross section of a portion of the display panel 100 corresponding to the display area DA of FIG. 1 in relation to a configuration of the display panel 100 according to an embodiment.

Referring to FIGS. 1 to 4, the display panel 100 may include a backplane BPL and a light emitting element layer EDL disposed on the backplane BPL. The backplane BPL and the light emitting element layer EDL may be bonded to each other so that the pixel circuit PXC and the light emitting element LE of each pixel PX may be electrically connected to each other.

The backplane BPL may include the pixel circuit PXC of each of the pixels PX. For example, the backplane BPL may be disposed in each pixel area of the display area DA, and may include circuit elements (e.g., a driving transistor, a switching transistor, and a capacitor) forming the pixel circuit PXC of the corresponding pixel PX.

The backplane BPL may be disposed in the entire area of the display panel 100 including the display area DA and the non-display area NDA. The backplane BPL may further include the lines electrically connected to the pixels PX and/or the pads PD.

In an embodiment, the backplane BPL may include a first backplane layer GBP and a second backplane layer SBP that include different structures and/or types of transistors. For example, the first backplane layer GBP may include a first substrate and first-type transistors disposed on the first substrate, and the second backplane layer SBP may include a second substrate and second-type transistors disposed on the second substrate.

In an embodiment, the backplane BPL may further include a line layer CNL disposed on the second backplane layer SBP. For example, the line layer CNL may be disposed between the second backplane layer SBP and the light emitting element layer EDL. The line layer CNL may include conductive patterns (or lines) for connecting the second backplane layer SBP and the light emitting element layer EDL to each other.

The second backplane layer SBP and the line layer CNL have been separately illustrated in FIG. 4, but embodiments are not limited thereto. For example, the line layer CNL may also be included in the second backplane layer SBP.

The light emitting element layer EDL may include a light emitting element LE of each of the pixels PX. For example, the light emitting element layer EDL may include a light emitting element LE disposed in each pixel area of the display area DA and electrically connected to the pixel circuit PXC of the corresponding pixel PX.

In an embodiment, the display panel 100 may further include an optical layer MLA disposed on the light emitting element layer EDL. The optical layer MLA may include an optical element for improving optical performance of the display panel 100. For example, the optical layer MLA may include a micro lens array including a micro lens disposed on the light emitting element LE of each of the pixels PX. By disposing the micro lens array on the light emitting element layer EDL, it is possible to efficiently control and/or disperse light emitted from the pixels PX and improve optical performance of the display panel 100.

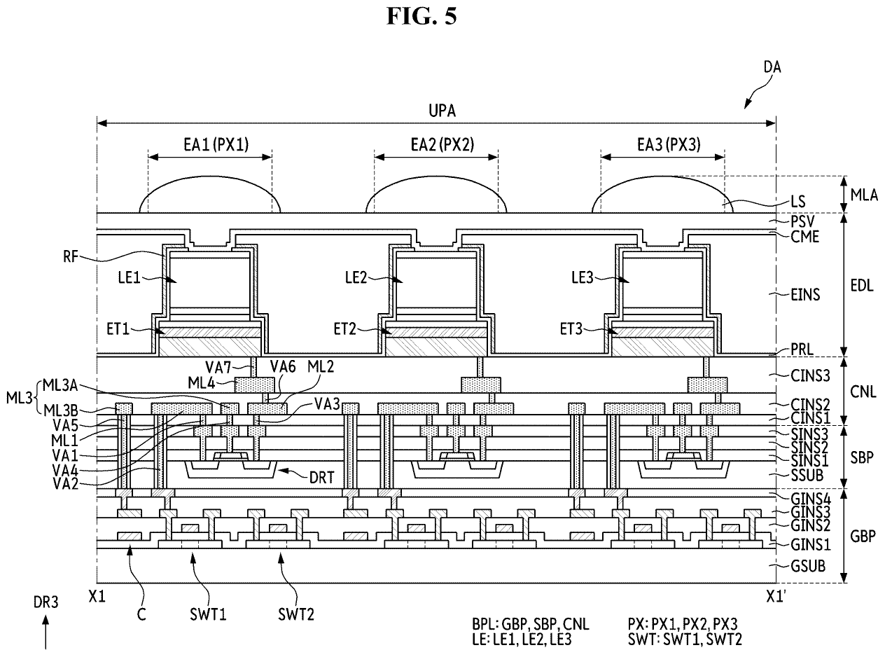

FIG. 5 is a schematic cross-sectional view illustrating a display area of the display device according to an embodiment. For example, FIG. 5 illustrates an embodiment of a cross section of a portion of the display area DA of FIGS. 3 and 4. FIG. 5 illustrates cross sections of a first pixel PX1, a second pixel PX2, and a third pixel PX3 positioned in a unit pixel area UPA as a cross section of the display panel 100 corresponding to line X1-X1′ of FIG. 3.

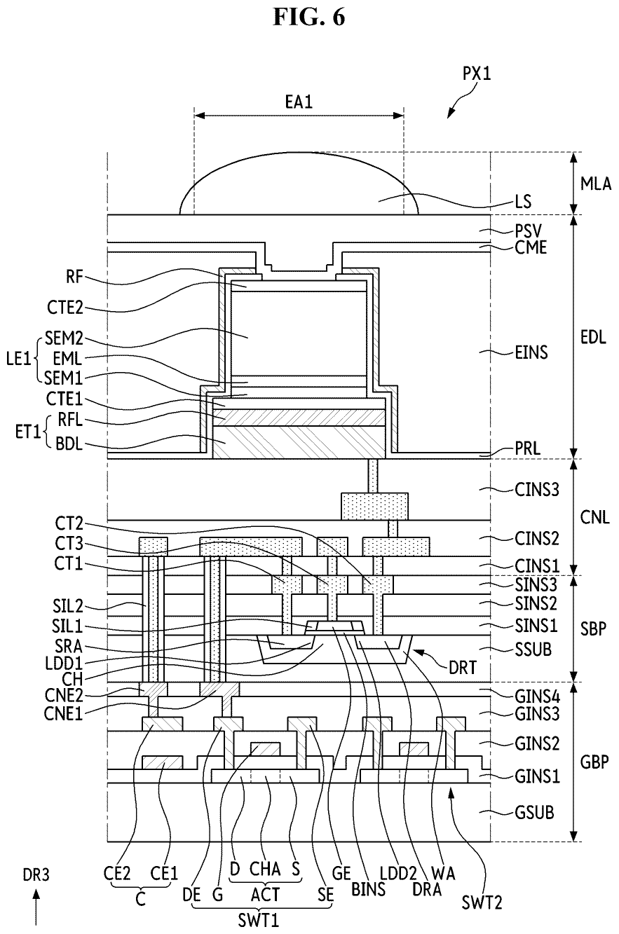

FIG. 6 is a schematic cross-sectional view illustrating a pixel of the display device according to an embodiment. For example, FIG. 6 illustrates an enlarged cross section of the first pixel PX1 of FIG. 5. In an embodiment, cross-sectional structures of the first pixel PX1, the second pixel PX2, and the third pixel PX3 may be substantially the same as or similar to each other.

Referring to FIGS. 5 and 6 in addition to FIGS. 1 to 4, the pixel PX may include circuit elements of the pixel circuit PXC disposed in the backplane BPL and a light emitting element LE disposed in the light emitting element layer EDL. For example, the pixel PX may include at least one switching transistor SWT, a driving transistor DRT, and a capacitor C disposed in each pixel area of the backplane BPL, and a light emitting element LE disposed in each pixel area of the light emitting element layer EDL.

It has been illustrated that FIGS. 5 and 6 that each pixel PX includes two switching transistors SWT including a first switching transistor SWT1 and a second switching transistor SWT2, but embodiments are not limited thereto. For example, the number or a connection structure of switching transistors SWT disposed in each pixel PX may be variously changed according to a configuration of the pixel circuit PXC.

A pixel area where each pixel PX is disposed may include an emission area where a light emitting element LE of the corresponding pixel PX is disposed. For example, a first pixel area where the first pixel PX1 is disposed may include a first emission area EA1 where a light emitting element LE of the first pixel PX1 (hereinafter referred to as a “first light emitting element LE1”) is disposed. A second pixel area where the second pixel PX2 is disposed may include a second emission area EA2 where a light emitting element LE of the second pixel PX2 (hereinafter referred to as a “second light emitting element LE2”) is disposed. A third pixel area where the third pixel PX3 is disposed may include a third emission area EA3 where a light emitting element LE of the third pixel PX3 (hereinafter referred to as a “third light emitting element LE3”) is disposed.

For example, each pixel area may further include a pixel circuit area where circuit elements of the pixel circuit PXC connected to the light emitting element LE of the corresponding pixel PX are disposed. The emission area and the pixel circuit area of each pixel PX may overlap each other, but embodiments are not limited thereto.

In embodiments, the switching transistors SWT and the driving transistors DRT of the pixels PX may be disposed on different substrates. For example, the switching transistors SWT of the pixels PX may be disposed on a first substrate GSUB and formed as the first backplane layer GBP, and the driving transistors DRT of the pixels PX may be disposed on a second substrate SSUB and formed as the second backplane layer SBP.

The switching transistors SWT and the driving transistors DRT of the pixels PX may be different types of transistors. For example, each of the switching transistors SWT of the pixels PX may be a thin film transistor (TFT) formed on the first substrate GSUB. For example, each of the driving transistors DRT of the pixels PX may be a metal oxide semiconductor field effect transistor (MOSFET) formed on the second substrate SSUB using a semiconductor process. As an example, MOSFET-based driving transistors DRT may be formed using a silicon semiconductor process. For example, the backplane BPL according to embodiments may be a hybrid backplane in which TFT-based switching transistors SWT formed on the first substrate GSUB and MOSFET-based driving transistors DRT formed on the second substrate SSUB are combined with each other.

In an embodiment, the first substrate GSUB and the second substrate SSUB may be made of different materials. For example, the first substrate GSUB may be a substrate made of a material suitable for forming the TFT, for example, a rigid insulating substrate such as a glass substrate, or may be a flexible insulating substrate including a polymer resin such as polyimide. A material or a characteristic of the first substrate GSUB is not particularly limited as long as it is suitable as a base member for forming the TFT.

The second substrate SSUB may be a substrate made of a material suitable for forming the MOSFET, for example, a semiconductor substrate such as a silicon wafer. A material or a characteristic of the second substrate SSUB is not particularly limited as long as it is suitable as a base member for forming the MOSTFT.

The first backplane layer GBP may include the first substrate GSUB and the switching transistors SWT disposed on the first substrate GSUB. In an embodiment, each of the switching transistors SWT may be a TFT, and the first backplane layer GBP may be a thin film transistor circuit board.

In an embodiment, the first backplane layer GBP may include circuit elements other than the driving transistor DRT among circuit elements forming the pixel circuit PXC of each pixel PX. For example, the first backplane layer GBP may include at least one switching transistor SWT included in each pixel PX, for example, the first switching transistor SWT1 and the second switching transistor SWT2 of each pixel PX. In an embodiment, at least one of the switching transistors SWT of each pixel PX may be electrically connected to the driving transistor DRT of each pixel PX. For example, the first backplane layer GBP may include the capacitor C (e.g., a storage capacitor) included in each pixel PX. In an embodiment, the capacitor C may be electrically connected to the driving transistor DRT of the corresponding pixel PX. As an example, the capacitor C may be electrically connected to a gate electrode GE of the driving transistor DRT.

In an embodiment, the first backplane layer GBP may further include connection electrodes (or contact terminals) for electrically connecting the circuit elements in the first backplane layer GBP and circuit elements of the second backplane layer SBP to each other. As an example, the first backplane layer GBP may further include a first connection electrode CNE1 electrically connected to the first switching transistor SWT1 of each pixel PX and a second connection electrode CNE2 electrically connected to the capacitor C of each pixel PX.

For example, the first backplane layer GBP may further include insulating layers. As an example, the first backplane layer GBP may further include a first insulating layer GINS1, a second insulating layer GINS2, a third insulating layer GINS3, and a fourth insulating layer GINS4 that are sequentially disposed or stacked on the first substrate GSUB.

Each switching transistor SWT may include an active layer ACT and a gate electrode G. In an embodiment, each switching transistor SWT may further include at least one of a source electrode SE and a drain electrode DE. In another embodiment, at least one switching transistor SWT may not include a separate source electrode SE and drain electrode DE, and a source region S and a drain region D may be connected (e.g., directly connected) to other circuit elements, connection patterns, lines, or the like, to function as a source electrode and a drain electrode, respectively. An embodiment in which each of the switching transistors SWT has a top-gate structure has been illustrated in FIGS. 5 and 6, but embodiments are not limited thereto. For example, at least one switching transistor SWT may also have a bottom-gate structure. Each of the switching transistors SWT may be a P-type or N-type transistor, and a connection direction may be changed according to a conductivity type of each of the switching transistors SWT.

The active layer ACT may be disposed on the first substrate GSUB. As an example, the active layer ACT may be formed (e.g., directly formed) on the first substrate GSUB or formed on a buffer layer disposed on the first substrate GSUB. The active layer ACT may include a semiconductor material. For example, the active layer ACT may include amorphous silicon, polycrystalline silicon, or an oxide semiconductor. The active layer ACT may include a channel region CHA, the source region S, and the drain region D. The source region S and the drain region D may be positioned on opposite sides of the channel region CHA, respectively. The source region S and the drain region D may have higher conductivity

### Than the Channel Region Cha.

The first insulating layer GINS1 may be disposed on the active layer ACT. For example, the first insulating layer GINS1 may cover the first substrate GSUB and the active layer ACT. The first insulating layer GINS1 may include at least one insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials), and may be formed as a single layer or multiple layers.

The gate electrode G may be disposed on the first insulating layer GINS1. The gate electrode G may include at least one conductive material, and may be formed as a single layer or multiple layers.

In an embodiment, a first capacitor electrode CE1 may be further disposed on the first insulating layer GINS1. The first capacitor electrode CE1 may form the capacitor C together with a second capacitor electrode CE2. The gate electrode G and the first capacitor electrode CE1 may be simultaneously formed, and may have the same conductive material and/or cross-sectional structure.

The second insulating layer GINS2 may be disposed on the gate electrode G and the first capacitor electrode CE1. For example, the second insulating layer GINS2 may cover the first insulating layer GINS1, the gate electrode G, and the first capacitor electrode CE1. The second insulating layer GINS2 may include at least one insulating material (e.g., an inorganic insulating material), and may be formed as a single layer or multiple layers.

The source electrode SE and the drain electrode DE may be disposed on the second insulating layer GINS2. The source electrode SE may penetrate through the first insulating layer GINS1 and the second insulating layer GINS2 and be electrically connected to the source region S. The drain electrode DE may penetrate through the first insulating layer GINS1 and the second insulating layer GINS2 and be electrically connected to the drain region D. Each of the source electrode SE and the drain electrode DE may include at least one conductive material, and may be formed as a single layer or multiple layers.

In an embodiment, the second capacitor electrode CE2 may be further disposed on the second insulating layer GINS2. The second capacitor electrode CE2 may overlap the first capacitor electrode CE1 in the third direction DR3. The source electrode SE, the drain electrode DE, and the second capacitor electrode CE2 may be simultaneously formed, and may have the same conductive material and/or cross-sectional structure.

The third insulating layer GINS3 may be disposed on the source electrode SE, the drain electrode DE, and the second capacitor electrode CE2. For example, the third insulating layer GINS3 may cover the second insulating layer GINS2, the source electrode SE, the drain electrode DE, and the second capacitor electrode CE2. The third insulating layer GINS3 may include at least one insulating material (e.g., an inorganic insulating material and/or an organic insulating material), and may be formed as a single layer or multiple layers.

The first connection electrode CNE1 and the second connection electrode CNE2 may be disposed on the third insulating layer GINS3. The first connection electrode CNE1 may penetrate through the third insulating layer GINS3 and be electrically connected to an electrode (e.g., the drain electrode DE) of the first switching transistor SWT1. The second connection electrode CNE2 may penetrate through the third insulating layer GINS3 and be electrically connected to an electrode (e.g., the second capacitor electrode CE2) of the first capacitor C. Each of the first connection electrode CNE1 and the second connection electrode CNE2 may include at least one conductive material, and may be formed as a single layer or multiple layers.

A portion of each of the first connection electrode CNE1 and the second connection electrode CNE2 may be exposed on a surface of the first backplane layer GBP. As an example, the entirety or a portion of an upper surface of each of the first connection electrode CNE1 and the second connection electrode CNE2 may be exposed on an upper surface of the first backplane layer GBP.

The fourth insulating layer GINS4 may be disposed around the first connection electrode CNE1 and the second connection electrode CNE2. For example, the fourth insulating layer GINS4 may be disposed on the third insulating layer GINS3, and may include openings exposing the first connection electrode CNE1 and the second connection electrode CNE2. An embodiment in which the first connection electrode CNE1, the second connection electrode CNE2, and the fourth insulating layer GINS4 are formed at the same height has been illustrated in FIGS. 5 and 6, but embodiments are not limited thereto. The fourth insulating layer GINS3 may include at least one insulating material (e.g., an inorganic insulating material and/or an organic insulating material), and may be formed as a single layer or multiple layers.

In an embodiment, the surface of the first backplane layer GBP may be substantially flat. For example, the upper surface of the first backplane layer GBP on which at least portions of the first connection electrode CNE1 and the second connection electrode CNE2 and the fourth insulating layer GINS4 are exposed may be substantially flat. Accordingly, bonding strength between the first backplane layer GBP and the second backplane layer SBP may be increased.

The second backplane layer SBP may be disposed on the first backplane layer GBP. The second backplane layer SBP may include the second substrate SSUB and the driving transistors DRT disposed on the second substrate SSUB. Each driving transistor DRT may be disposed in each pixel area of the display area DA. Each driving transistor DRT may be electrically connected to the light emitting element LE of the corresponding pixel PX. In an embodiment, the driving transistor DRT may be a MOSFET, and the second backplane layer SBP may be a semiconductor circuit board formed by a semiconductor process using a semiconductor substrate such as a silicon wafer.

In an embodiment, the second backplane layer SBP may further include contact terminals (or lines) electrically connected to the circuit elements in the second backplane layer SBP. As an example, the second backplane layer SBP may further include a first contact terminal CT1, a second contact terminal CT2, and a third contact terminal CT3 electrically connected to the driving transistor DRT of each pixel PX.

The second backplane layer SBP may further include insulating layers. As an example, the second backplane layer SBP may further include a fifth insulating layer SINS1, a sixth insulating layer SINS2, and a seventh insulating layer SINS3 that are sequentially disposed or stacked on the second substrate SSUB.

The second substrate SSUB may be disposed on the first backplane layer GBP. For example, the second substrate SSUB may be disposed on the first connection electrode CNE1, the second connection electrode CNE2, and the fourth insulating layer GINS4.

The second substrate SSUB may be a semiconductor substrate such as a silicon substrate (e.g., a silicon wafer), a germanium substrate, or a silicon-germanium substrate. The second substrate SSUB may be a substrate doped with first-type impurities. Well regions WA may be disposed in an upper surface of the second substrate SSUB. The well regions WA may be regions doped with second-type impurities. The second-type impurities may be different from the first-type impurities. As an example, in case that the first-type impurities are p-type impurities, the second-type impurities may be n-type impurities. In another example, in case that the first-type impurities are n-type impurities, the second-type impurities may be p-type impurities. Each of the well regions WA may include a source region SRA corresponding to a source electrode of the driving transistor DRT, a drain region DRA corresponding to a drain electrode of the driving transistor DRT, and a channel region CH disposed between the source region SRA and the drain region DRA.

The driving transistor DRT may include the source region SRA, the drain region DRA, and the channel region CH disposed in each well region WA, and the gate electrode GE overlapping the channel region CH. The driving transistor DRT may be a MOSFET-based transistor formed using a semiconductor process, and may have an advantage of low power consumption. For example, the driving transistor DRT formed as a MOSFET may have a very small subthreshold swing. Accordingly, a voltage applied to the driving transistor DRT may be reduced, and a voltage difference between the first driving voltage VDD and the second driving voltage VSS for ensuring an operation area margin of the driving transistor DRT may be reduced. Accordingly, power consumption of the driving transistor DRT and the display device 10 including the driving transistor DRT may be reduced.

A bottom insulating film BINS may be disposed between the gate electrode GE and the well region WA. First side surface insulating films SIL1 may be disposed on side surfaces of the gate electrode GE. The first side surface insulating films SIL1 may be disposed on the bottom insulating film BINS.

Each of the source region SRA and the drain region DRA may be a region doped with the first-type impurities. The gate electrode GE may overlap the well region WA in the third direction DR3. The channel region CH may overlap the gate electrode GE in the third direction DR3. The source region SRA may be disposed on one side of the gate electrode GE, and the drain region DRA may be disposed on the other side of the gate electrode GE.

Each of the well regions WA may further include a first low-concentration impurity region LDD1 disposed between the channel region CH and the source region SRA and a second low-concentration impurity region LDD2 disposed between the channel region CH and the drain region DRA. The first low-concentration impurity region LDD1 may be a region having a lower impurity concentration than the source region SRA due to the bottom insulating film BINS. The second low-concentration impurity region LDD2 may be a region having a lower impurity concentration than the drain region DRA due to the bottom insulating film BINS. A distance between the source region SRA and the drain region DRA may increase by the first low-concentration impurity region LDD1 and the second low-concentration impurity region LDD2. Accordingly, a length of the channel region CH of each of the driving transistors DRT may increase, thereby preventing punch-through and hot carrier phenomena caused by a short channel.

The fifth insulating layer SINS1 may be disposed on the second substrate SSUB. The fifth insulating film SINS1 may be formed as a silicon carbonitride (SiCN) or silicon oxide (SiOₓ)-based inorganic film, but embodiments are not limited thereto.

The sixth insulating layer SINS2 may be disposed on the fifth insulating layer SINS1. The sixth insulating film SINS2 may be formed as a silicon oxide (SiOₓ)-based inorganic film, but embodiments are not limited thereto.

The first contact terminal CT1, the second contact terminal CT2, and the third contact terminal CT3 may be disposed on the sixth insulating layer SINS2. Each of the first contact terminal CT1, the second contact terminal CT2, and the third contact terminal CT3 may penetrate through the fifth insulating layer SINS1 and the sixth insulating layer SINS2 and be electrically connected to any one of the source region SRA, the drain region DRA, and the gate electrode GE of the driving transistor DRT. As an example, the first contact terminal CT1 may be electrically connected to the source region SRA of the driving transistor DRT, the second contact terminal CT2 may be electrically connected to the drain region DRA of the driving transistor DRT, and the third contact terminal CT3 may be electrically connected to the gate electrode GE of the driving transistor DRT.

Each of the first contact terminal CT1, the second contact terminal CT2, and the third contact terminal CT3 may be electrically connected to the circuit element (e.g., the first switching transistor SWT1 or the capacitor C) of the first backplane layer GBP or the light emitting element LE through at least one conductive pattern (or line) disposed in the line layer CNL. For example, one of the first contact terminal CT1 and the second contact terminal CT2 may be electrically connected to the first switching transistor SWT1, and the other of the first contact terminal CT1 and the second contact terminal CT2 may be electrically connected to the light emitting element LE. The driving transistor DRT may be a P-type transistor or a N-type transistor, and a connection direction of the driving transistor DRT may be changed according to a conductivity type of the driving transistor DRT.

The driving transistor DRT may be electrically connected between the first switching transistor SWT1 and the light emitting element LE through conductive patterns. As an example, the first contact terminal CT1 may be electrically connected to the first connection electrode CNE1 through a first conductive pattern ML1, and may be electrically connected to an electrode (e.g., the drain electrode DE or the source electrode SE) of the first switching transistor SWT1 through the first connection electrode CNE1. For example, the second contact terminal CT2 may be electrically connected to a pixel electrode (e.g., a first pixel electrode ET1, a second pixel electrode ET2, or a third pixel electrode ET3) of each pixel PX through a second conductive pattern ML2 and a fourth conductive pattern ML4, and may be electrically connected to the light emitting element LE through the pixel electrode. In an embodiment, the gate electrode GE of the driving transistor DRT may be electrically connected to the capacitor C. For example, the third contact terminal CT3 may be electrically connected to the second connection electrode CNE2 through a third conductive pattern ML3, and may be electrically connected to an electrode (e.g., the second capacitor electrode CE2) of the capacitor C through the second connection electrode CNE2. In FIGS. 5 and 6, two patterns ML3A and ML3B of the third conductive pattern ML3 disposed on opposite sides of the first conductive pattern ML1 may be a pattern (e.g., single pattern) connected to each other in plan view.

Each of the first contact terminal CT1, the second contact terminal CT2, and the third contact terminal CT3 may include at least one conductive material (e.g., any one of copper (Cu), aluminum (Al), tungsten (W), molybdenum (Mo), chromium (Cr), gold (Au), titanium (Ti), nickel (Ni), and neodymium (Nd), or alloys thereof), and may be formed as a single layer or multiple layers.

The seventh insulating layer SINS3 may be disposed on side surfaces of each of the first contact terminal CT1, the second contact terminal CT2, and the third contact terminal CT3. An upper surface (or a portion of the upper surface) of each of the first contact terminal CT1, the second contact terminal CT2, and the third contact terminal CT3 may not be covered by the seventh insulating layer SINS3, and may be exposed on an upper surface of the second backplane layer SBP. The seventh insulating film SINS3 may be formed as a silicon oxide (SiOₓ)-based inorganic film, but embodiments are not limited thereto.

The line layer CNL (or a light emitting element backplane) may include conductive patterns, through-electrodes, and insulating layers. As an example, the line layer CNL may include a first conductive pattern ML1, a second conductive pattern ML2, a third conductive pattern ML3, a fourth conductive pattern ML4, a first through-electrode VA1, a second through-electrode VA2, a third through-electrode VA3, a fourth through-electrode VA4, a fifth through-electrode VA5, a sixth through-electrode VA6, a seventh through-electrode VA7, an eighth insulating layer CINS1, a ninth insulating layer CINS2, and a tenth insulating layer CINS3. Some of the through-electrodes may pass through the second backplane layer SBP.

The eighth insulating layer CINS1 may be disposed on the second backplane layer SBP. The first conductive pattern ML1, the second conductive pattern ML2, and the third conductive pattern ML3 may be disposed on the eighth insulating layer CINS1.

The first conductive pattern ML1 may be electrically connected to the first contact terminal CT1 by the first through-electrode VA1 penetrating through the eighth insulating layer CINS1. For example, the first conductive pattern ML1 may be electrically connected to the first connection electrode CNE1 by the second through-electrode VA2 penetrating through the second substrate SSUB, the fifth insulating layer SINS1, the sixth insulating layer SINS2, the seventh insulating layer SINS3, and the eighth insulating layer CINS1.

The second conductive pattern ML2 may be electrically connected to the second contact terminal CT2 by the third through-electrode VA3 penetrating through the eighth insulating layer CINS1.

The third conductive pattern ML3 may be electrically connected to the third contact terminal CT3 by the fourth through-electrode VA4 penetrating through the eighth insulating layer CINS1. For example, the third conductive pattern ML3 may be electrically connected to the second connection electrode CNE2 by the fifth through-electrode VA5 penetrating through the second substrate SSUB, the fifth insulating layer SINS1, the sixth insulating layer SINS2, the seventh insulating layer SINS3, and the eighth insulating layer CINS1. In an embodiment, second side insulating films SIL2 may be disposed on side surfaces of each of the second through-electrode VA2 and the fifth through-electrode VA5.

The ninth insulating layer CINS2 may be disposed on the eighth insulating layer CINS1, the first conductive pattern ML1, the second conductive pattern ML2, and the third conductive pattern ML3. The fourth conductive pattern ML4 may be disposed on the ninth insulating layer CINS2.

The fourth conductive pattern ML4 may be disposed on the ninth insulating layer CINS2. The fourth conductive pattern ML4 may be electrically connected to the second conductive pattern ML2 by the sixth through-electrode VA6 penetrating through the ninth insulating layer CINS2. For example, the fourth conductive pattern ML4 may be electrically connected to the light emitting element LE (or the pixel electrode electrically connected to the light emitting element LE) by the seventh through-electrode VA7 penetrating through the tenth insulating layer CINS3.

The tenth insulating layer CINS3 may be disposed on the ninth insulating layer CINS2 and the fourth conductive pattern ML4. The light emitting element layer EDL may be disposed on the tenth insulating layer CINS3.

A structure of the line layer CNL has been relatively simply illustrated in FIGS. 5 and 6, but embodiments are not limited thereto. As an example, the line layer CNL may also include a greater number of conductive layers and insulating layers. Each of the conductive layers of the line layer CNL may include at least one conductive pattern disposed in each pixel area.

Each of the conductive patterns (e.g., the first conductive pattern ML1, the second conductive pattern ML2, the third conductive pattern ML3, and the fourth conductive pattern ML4) and the through-electrodes (e.g., the first through-electrode VA1, the second through-electrode VA2, the third through-electrode VA3, the fourth through-electrode VA4, the fifth through-electrode VA5, the sixth through-electrode VA6, and the seventh through-electrode VA7) of the line layer CNL may include at least one conductive material. As an example, each of the conductive patterns and the through-electrodes of the line layer CNL may be made of any one of copper (Cu), aluminum (Al), tungsten (W), molybdenum (Mo), chromium (Cr), gold (Au), titanium (Ti), nickel (Ni), and neodymium (Nd), or alloys thereof. In an embodiment, the conductive patterns and the through-electrodes of the line layer CNL may include the same conductive material, but embodiments are not limited thereto.

Each of the insulating layers (e.g., the eighth insulating layer CINS1, the ninth insulating layer CINS2, and the tenth insulating layer CINS3) of the line layer CNL may include at least one insulating material (e.g., an inorganic insulating material or an organic insulating material), and may be formed as a single layer or multiple layers. As an example, each of the eighth insulating layer CINS1, the ninth insulating layer CINS2, and the tenth insulating layer CINS3 may be formed as a silicon oxide (SiOₓ)-based inorganic film, but embodiments are not limited thereto.

The light emitting element layer EDL may be disposed on the backplane BPL. As an example, the light emitting element layer EDL may be disposed on the line layer CNL (or the second backplane layer SBP) of the backplane BPL.

The light emitting element layer EDL may include pixel electrodes ET1, ET2, and ET3, light emitting elements LE, a common electrode CME, and a passivation layer PSV. In an embodiment, the light emitting element layer EDL may further include at least one of contact electrodes CTE1 and CTE2 disposed on at least one surface of the light emitting elements LE, a protective film PRL surrounding side surfaces and the like of the light emitting elements LE, a reflective film RF disposed around the light emitting elements LE, and an eleventh insulating layer EINS.

The pixel electrodes ET1, ET2, and ET3 may be disposed on the backplane BPL. As an example, the pixel electrodes ET1, ET2, and ET3 may be disposed on the tenth insulating layer CINS3.

The pixel electrodes ET1, ET2, and ET3 may be disposed in the respective pixel areas where the pixels PX are disposed, and may be separated from each other. For example, a pixel electrode of the first pixel PX1 (hereinafter referred to as a “first pixel electrode ET1”) may be individually disposed in the first pixel area where the first pixel PX1 is disposed, a pixel electrode of the second pixel PX2 (hereinafter referred to as a “second pixel electrode ET2”) may be individually disposed in the second pixel area where the second pixel PX2 is disposed, and a pixel electrode of the third pixel PX3 (hereinafter, referred to as a “third pixel electrode ET3”) may be individually disposed in the third pixel area where the third pixel PX3 is disposed.

Each of the pixel electrodes ET1, ET2, and ET3 may be electrically connected to the fourth conductive pattern ML4 through the seventh through-electrode VA7, and may be electrically connected to the driving transistor DRT through at least one conductive pattern including the fourth conductive pattern ML4. For example, each of the pixel electrodes ET1, ET2, and ET3 may be electrically connected to a first semiconductor layer SEM1 of the light emitting element LE through a first contact electrode CTE1.

For example, the first pixel electrode ET1 may be electrically connected between the fourth conductive pattern ML4 and the first light emitting element LE1 of the first pixel PX1. The second pixel electrode ET2 may be electrically connected between the fourth conductive pattern ML4 and the second light emitting element LE2 of the second pixel PX2. The third pixel electrode ET3 may be electrically connected between the fourth conductive pattern ML4 and the third light emitting element LE3 of the third pixel PX3.

The pixel electrodes ET1, ET2, and ET3 may physically and/or electrically bond the backplane BPL and the light emitting elements LE to each other. In an embodiment, the pixel electrodes ET1, ET2, and ET3 may be bonding electrodes (or bonding pads) for stably disposing or bonding the light emitting elements LE on or onto the backplane BPL. As an example, the first pixel electrode ET1 may be a first bonding electrode corresponding to a bonding electrode of the first pixel PX1, the second pixel electrode ET2 may be a second bonding electrode corresponding to a bonding electrode of the second pixel PX2, and the third pixel electrode ET3 may be a third bonding electrode corresponding to a bonding electrode of the third pixel PX3.

However, types of the pixel electrodes ET1, ET2, and ET3 are not limited thereto, and types, structures, and/or materials of the pixel electrodes ET1, ET2, and ET3 may be changed according to a bonding structure, a bonding method, or the like, between the backplane BPL and the light emitting elements LE. Hereinafter, an embodiment in which pixel electrodes ET1, ET2, and ET3 are bonding electrodes will be described.

Each of the pixel electrodes ET1, ET2, and ET3 may be formed as a single layer or multiple layers including a bonding layer BDL (also referred to as a “bonding metal layer”). As an example, each of the pixel electrodes ET1, ET2, and ET3 may include a bonding layer BDL and a reflective layer RFL disposed on the bonding layer BDL.

The bonding layer BDL may include a conductive material suitable for a bonding process. For example, the bonding layer BDL may include a metal or a metal alloy having excellent electrical and thermal conductivity or a transparent conductive material capable of a bonding process. Examples of the metal or the metal alloy that are included in the bonding layer BDL may include eutectic metals such as a gold (Au)-tin (Sn) alloy, titanium (Ti), zirconium (Zr), nickel (Ni), or chromium (Cr). Examples of the transparent conductive material that are included in the bonding layer BDL may include indium tin oxide (ITO), zinc oxide (ZnO), or the like. The bonding layer BDL may also be made of other conductive materials.

In an embodiment, the bonding layer BDL may have a thickness enough to appropriately or readily perform the bonding process. As an example, the bonding layer BDL may have a thickness of several hundred of nanometers (nm) (e.g., a thickness in the range of about 200 nm to about 500 nm), but embodiments are not limited thereto.

The reflective layer RFL may be disposed on the bonding layer BDL. In an embodiment, the reflective layer RFL may include a conductive material (e.g., a metal) having a high light reflectivity. For example, the reflective layer RFL may include aluminum (Al) or include other metals (e.g., molybdenum (Mo), titanium (Ti), copper (Cu), silver (Ag), magnesium (Mg), platinum (Pt), palladium (Pd), gold (Au), nickel (Ni), neodymium (Nd), iridium (Ir), chromium (Cr), etc.) having a high light reflectivity. In another embodiment, the reflective layer RFL may include transparent conductive layers that function as a distributed Bragg reflector (DBR).

In an embodiment, the reflective layer RFL may cover (e.g., completely cover) a lower surface of each of the light emitting elements LE. Accordingly, light that has traveled from each of the light emitting elements LE in a downward direction may be effectively reflected, such that light efficiency of the light emitting element LE and the pixel PX including the light emitting element LE may be increased.

In an embodiment, each of the pixel electrodes ET1, ET2, and ET3 may further include a barrier layer covering at least one surface of the bonding layer BDL and the reflective layer RFL. As an example, each of the pixel electrodes ET1, ET2, and ET3 may further include at least one of a first barrier layer covering a lower surface of the bonding layer BDL, a second barrier layer covering an upper surface of the bonding layer BDL and a lower surface of the reflective layer RFL, and a third barrier layer covering an upper surface of the reflective layer RFL.

The barrier layer may include a material suitable for diffusion prevention (e.g., intermetallic diffusion prevention). For example, the barrier layer may be made of a material and/or be formed at a thickness capable of ensuring conductivity of each of the pixel electrodes ET1, ET2, and ET3. In an embodiment, the barrier layer may include a material having a high intermetallic diffusion prevention effect, such as titanium (Ti), titanium nitride (TiN), nickel (Ni), or other diffusion prevention materials, and may be formed at a thickness smaller than or equal to a thickness of each of the reflective layer RFL and the bonding layer BDL. For example, the barrier layer may be formed as a thin film including a material suitable for preventing diffusion of the metal included in the bonding layer BDL and/or the reflective layer RFL.

The light emitting elements LE may be disposed on the pixel electrodes ET1, ET2, and ET3. For example, the light emitting element LE of each pixel PX may be bonded onto (or connected to) the pixel electrode of the corresponding pixel PX.

In an embodiment, the light emitting elements LE of the first pixel PX1, the second pixel PX2, and the third pixel PX3 may be disposed at/in a same layer (or a same level) in the light emitting element layer EDL. In case that the light emitting elements LE of the first pixel PX1, the second pixel PX2, and the third pixel PX3 are disposed at/in the same layer, a structure of the display panel 100 may be simplified, and a thickness of the display panel 100 may be reduced. However, embodiments are not limited thereto. For example, the light emitting elements LE of the first pixel PX1, the second pixel PX2, and the third pixel PX3 may also be disposed at/in different layers in the light emitting element layer EDL.

In an embodiment, the first contact electrode CTE1 may be disposed above each of the pixel electrodes ET1, ET2, and ET3, and the light emitting element LE of each pixel PX may be disposed on the first contact electrode CTE1. The first contact electrode CTE1 has been illustrated as a separate component from the light emitting element LE in FIG. 6, but embodiments are not limited thereto. For example, the first contact electrode CTE1 may also be considered as a component included in the light emitting element LE. The first contact electrode CTE1 may be formed or etched together with the light emitting element LE or be formed or etched separately from the light emitting element LE.

In another embodiment, the light emitting element LE or the pixel PX may not include the first contact electrode CTE1. For example, the light emitting element LE may be disposed (e.g., directly disposed) on the first pixel electrode ET1, the second pixel electrode ET2, or the third pixel electrode ET3 of each pixel PX.

The display panel 100 having a structure in which the pixel electrodes ET1, ET2, and ET3 are disposed on the backplane BPL and the light emitting elements LE are bonded (or connected) to the backplane BPL by the pixel electrodes ET1, ET2, and ET3 has been illustrated in FIGS. 5 and 6, but a structure of the display panel 100 according to embodiments is not limited thereto. For example, the light emitting elements LE may also be appropriately disposed on the backplane BPL by utilizing an adhesive layer, connection electrodes, lines, and the like, without using a bonding method.

The first contact electrode CTE1 may be disposed on the first pixel electrode ET1, the second pixel electrode ET2, or the third pixel electrode ET3 of each pixel PX. The first contact electrode CTE1 may be disposed on a surface (e.g., a lower surface) of the first semiconductor layer SEM1 included in the light emitting element LE. The first contact electrode CTE1 may protect the first semiconductor layer SEM1 and smoothly connect the light emitting element LE to the first pixel electrode ET1, the second pixel electrode ET2, or the third pixel electrode ET3 of each pixel PX.

The first contact electrode CTE1 may include a metal, a metal oxide, or other conductive materials. In an embodiment, the first contact electrode CTE1 may include a transparent conductive material (e.g., ITO, indium zinc oxide (IZO), or other transparent conductive materials), but embodiments are not limited thereto.

Each of the light emitting elements LE may be disposed on the first contact electrode CTE1 (or the first pixel electrode ET1, the second pixel electrode ET2, or the third pixel electrode ET3) of the corresponding pixel PX. Each of the light emitting elements LE may be electrically connected to the driving transistor DRT of the corresponding pixel PX via the first contact electrode CTE1, the pixel electrode (e.g., the first pixel electrode ET1, the second pixel electrode ET2, or the third pixel electrode ET3) of the corresponding pixel PX, and the like.

Each of the light emitting elements LE may include the first semiconductor layer SEM1, a light emitting layer EML, and a second semiconductor layer SEM2 that are sequentially disposed on the first contact electrode CTE1. For example, the first semiconductor layer SEM1, the light emitting layer EML, and the second semiconductor layer SEM2 may be sequentially disposed or stacked on the first contact electrode CTE1 along the third direction DR3. In an embodiment, the first semiconductor layer SEM1, the light emitting layer EML, and the second semiconductor layer SEM2 may be formed from a semiconductor epitaxial stack or epi-layers formed by epitaxial growth on a growth substrate including a semiconductor material. As an example, each of the light emitting elements LE may be a micro light emitting diode including the first semiconductor layer SEM1, the light emitting layer EML, and the second semiconductor layer SEM2.

In an embodiment, the light emitting elements LE may be formed by etching the semiconductor epitaxial stack or the epi-layers grown on the growth substrate on the growth substrate, and may be disposed on or bonded onto (or connected to) the pixel electrodes ET1, ET2, and ET3 using at least one transfer substrate. In another embodiment, the light emitting elements LE may be formed by disposing or bonding the semiconductor epitaxial stack or the epi-layers grown on the growth substrate on or onto the backplane BPL by a wafer-to-wafer bonding process or the like, and then etching the semiconductor epitaxial stack or the epi-layers. The pixel electrodes ET1, ET2, and ET3 may be etched and separated into individual patterns after the light emitting elements LE are formed or disposed on the backplane BPL or be separated into individual patterns before the light emitting elements LE are formed or disposed on the backplane BPL.

The first semiconductor layer SEM1 may include a semiconductor material doped with first-type impurities. For example, the first semiconductor layer SEM1 may include a nitride-based semiconductor material, a phosphide-based semiconductor material, or other semiconductor materials, and may be doped with the first-type impurities. In an embodiment, the first semiconductor layer SEM1 may be a p-type semiconductor layer (e.g., p-GaN) doped with p-type impurities such as Mg, Zn, Ca, Se, or Ba, but embodiments are not limited thereto.

The light emitting layer EML may be disposed on the first semiconductor layer SEM1. For example, the light emitting layer EML may be disposed between the first semiconductor layer SEM1 and the second semiconductor layer SEM2. The light emitting layer EML may emit light by recombination of electron-hole pairs generated according to electrical signals applied through the first semiconductor layer SEM1 and the second semiconductor layer SEM2.

The light emitting layer EML may include a nitride-based semiconductor material, a phosphide-based semiconductor material, or other semiconductor materials, and may have a single quantum well structure or multiple quantum well structure. In an embodiment, the light emitting layer EML may have a multiple quantum well structure including a quantum well layer including InGaN and a barrier layer including GaN, AlGaN, or GaAlN, but embodiments are not limited thereto. In an embodiment, in case that the light emitting layer EML includes InGaN, a color of light emitted from the light emitting layer EML may be controlled or changed by adjusting a content of indium (In).

The light emitting layer EML may emit light of a visible ray wavelength band such as light of a wavelength band of about 400 nm to about 900 nm. For example, the light emitting layer EML may emit blue light having a peak wavelength of a range of about 440 nm to about 480 nm, green light having a peak wavelength of a range of about 510 nm to about 550 nm, or red light having a peak wavelength of a range of about 610 nm to about 650 nm. As an example, the light emitting layer EML of the first light emitting element LE1 may emit red light, the light emitting layer EML of the second light emitting element LE2 may emit green light, and the light emitting layer EML of the third light emitting element LE3 may emit blue light. However, embodiments are not limited thereto, and the light emitting layer EML may also emit light of a color or a wavelength band other than the colors or the wavelength bands exemplified above.

The second semiconductor layer SEM2 may include a semiconductor material doped with second-type impurities. For example, the second semiconductor layer SEM2 may include a nitride-based semiconductor material, a phosphide-based semiconductor material, or other semiconductor materials, and may be doped with the second-type impurities. In an embodiment, the second semiconductor layer SEM2 may be an n-type semiconductor layer (e.g., n-GaN) doped with n-type impurities such as Si, Ge, or Sn, but embodiments are not limited thereto.

In an embodiment, a second contact electrode CTE2 may be disposed on each light emitting element LE, and the common electrode CME may be disposed on the second contact electrode CTE2. For example, the second semiconductor layer SEM2 of the light emitting element LE may be electrically connected to the common electrode CME through the second contact electrode CTE2.

The second contact electrode CTE2 has been illustrated as a separate component from the light emitting element LE in FIG. 6, but embodiments are not limited thereto. For example, the second contact electrode CTE2 may also be considered as a component included in the light emitting element LE. The second contact electrode CTE2 may be formed or etched together with the light emitting element LE or be formed or etched separately from the light emitting element LE.

In another embodiment, the light emitting element LE or the pixel PX may not include the second contact electrode CTE2. For example, the common electrode CME may be connected (e.g., directly connected) to or in contact with the light emitting element LE.

The second contact electrode CTE2 may be disposed on a surface (e.g., an upper surface) of the second semiconductor layer SEM2. The second contact electrode CTE2 may protect the second semiconductor layer SEM2 and smoothly connect the light emitting element LE to the common electrode CME.

The second contact electrode CTE2 may include a metal, a metal oxide, or other conductive materials. In an embodiment, the second contact electrode CTE2 may be formed as a transparent electrode layer including a transparent conductive material (e.g., ITO, IZO, or other transparent conductive materials). Accordingly, light generated from the light emitting element LE may be transmitted through the second contact electrode CTE2 and emitted to an upper portion of the light emitting element LE.

The light emitting elements LE may be surrounded by the protective film PRL or the like. For example, the side surface of each of the light emitting elements LE may be surrounded by the protective film PRL and the reflective film RF.

The protective film PRL may surround the side surfaces of the light emitting elements LE. In an embodiment, the protective film PRL may further surround a side surface of at least one of the pixel electrodes ET1, ET2, and ET3, the first contact electrode CTE1, and the second contact electrode CTE2. As an example, the protective film PRL may be disposed (e.g., entirely disposed) in the display area DA to surround the side surfaces of the light emitting elements LE, the pixel electrodes ET1, ET2, and ET3, the first contact electrode CTE1, and the second contact electrode CTE2.

The protective film PRL may include an opening exposing a portion, for example, an upper surface, of each of the light emitting elements LE or the second contact electrodes CTE2. For example, the protective film PRL may include an opening exposing a portion (e.g., a portion of the upper surface) of each light emitting element LE or second contact electrode CTE2. In a portion where the protective film PRL is opened, the light emitting element LE or the second contact electrode CTE2 may be connected to the common electrode CME.

The protective film PRL may include at least one insulating material of silicon oxide (SiOₓ), silicon nitride (SiNₓ), aluminum oxide (AlₓO_{y}), titanium oxide (TiₓO_{y}), and hafnium oxide (HfOₓ), or other insulating materials. The protective film PRL may protect the light emitting element LE and increase electrical stability of the light emitting element LE.

The reflective film RF may be disposed on at least a portion of the protective film PRL. For example, the reflective film RF may be disposed on a portion of the protective film PRL surrounding the side surface of each of the light emitting elements LE.

The reflective film RF may surround the side surface of each of the light emitting elements LE. For example, in plan view, the reflective film RF may surround the light emitting elements LE.

The reflective film RF may reflect and recirculate light generated from each of the light emitting elements LE and directed toward a lateral direction or the like. Light emission efficiency of each of the light emitting elements LE (e.g., a ratio of light emitted to the upper portion of the light emitting element LE) may be increased by the reflective film RF.

In an embodiment, the reflective film RF may include a metal having a high reflectivity, such as aluminum (Al). In another embodiment, the reflective film RF may include a distributed Bragg reflector. As an example, the reflective film RF may include at least one pair (e.g., two or more pairs) of a first layer and a second layer that have different refractive indices and are alternately or sequentially disposed. One of the first layer and the second layer may be a low refractive layer, and the other of the first layer and the second layer may be a high refractive layer having a higher refractive index than the low refractive layer. Each of the first layer and the second layer may be formed as an inorganic film made of silicon nitride (SiNₓ), silicon oxynitride (SiOₓN_{y}), silicon oxide (SiOₓ), titanium oxide (TiₓO_{y}), aluminum oxide (AlₓO_{y}), or the like.

The eleventh insulating layer EINS may be disposed on the protective film PRL and the reflective film RF. The eleventh insulating layer EINS may be disposed around the light emitting elements LE so as to surround each of the light emitting elements LE. As an example, the eleventh insulating layer EINS may also be disposed between the light emitting elements LE.

In an embodiment, the eleventh insulating layer EINS may be formed at a height greater than or equal to a height of the light emitting elements LE, and may be opened above each of the light emitting elements LE. For example, the eleventh insulating layer EINS may include openings exposing portions of the upper surfaces of the light emitting elements LE.

The eleventh insulating layer EINS may be formed as a single layer or multiple layers including at least one insulating material. As an example, the eleventh insulating layer EINS may be a single-layer or multilayer inorganic film including silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials). In another example, the eleventh insulating layer EINS may be an organic film including an organic insulating material.

The common electrode CME may be disposed on the light emitting elements LE, the second contact electrodes CTE2, and the eleventh insulating layer EINS.

In an embodiment, the common electrode CME may be disposed (e.g., entirely disposed) in the display area DA. For example, the common electrode CME may be a common layer shared by the light emitting elements LE of the display area DA and the pixels PX including the light emitting elements LE.

The common electrode CME may be electrically connected to the light emitting elements LE. For example, openings may be formed in the protective film PRL and the eleventh insulating layer EINS above each of the light emitting elements LE, and the common electrode CME may be connected to the second contact electrodes CTE2 (or the light emitting elements LE) in the openings.

In an embodiment, the common electrode CME may be electrically connected to the second contact electrodes CTE2, and may be electrically connected to the second semiconductor layers SEM2 of the light emitting elements LE through the second contact electrodes CTE2. In another embodiment, the pixels PX may not include the second contact electrodes CTE2, and the common electrode CME may be in contact with (e.g., in direct contact with) the upper surfaces of the light emitting elements LE and be electrically connected to the second semiconductor layers SEM2 of the light emitting elements LE.

In an embodiment, the common electrode CME may be electrically connected to a power line formed on the backplane BPL inside and/or outside the display area DA. As an example, the common electrode CME may be electrically connected to a power line (e.g., the second power line VSL of FIG. 2) formed on the backplane BPL in the peripheral area PHA adjacent (e.g., immediately/directly adjacent) to the display area DA. Accordingly, the common electrode CME may receive the second driving voltage VSS from the second power line VSL. In an embodiment, the common electrode CME may function as a cathode electrode of each of the light emitting elements LE or the pixels PX. In another embodiment, the display panel 100 may have a common-anode structure, and the common electrode CME may be connected to the first power line VDL to which the first driving voltage VDD is applied and may function as an anode electrode of each of the light emitting elements LE or the pixels PX. In case that the display panel 100 has the common-anode structure, conductivity types or positions of the first semiconductor layer SEM1 and the second semiconductor layer SEM2 included in the light emitting element LE may be reversely changed or modified.

The common electrode CME may include a conductive material capable of transmitting light. For example, the common electrode CME may be made of ITO, IZO, or other transparent conductive materials.

The passivation layer PSV may be disposed on the common electrode CME. In an embodiment, the passivation layer PSV may be disposed (e.g., entirely disposed) in the display area DA so as to cover the common electrode CME.

In an embodiment, an upper surface of the passivation layer PSV may be substantially flat. For example, the passivation layer PSV may be made of a material and/or be formed at a thickness suitable for having a substantially flat upper surface or be planarized by a planarization process performed after film formation.

The passivation layer PSV may include at least one insulating material, and may have a single-layer or multilayer structure. In an embodiment, the passivation layer PSV may include an inorganic insulating material (e.g., silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials), but embodiments are not limited thereto.

The optical layer MLA may be disposed on the light emitting element layer EDL. As an example, the optical layer MLA may be disposed on the passivation layer PSV of the light emitting element layer EDL.

The optical layer MLA may include a lens LS overlapping each of the light emitting elements LE. For example, the optical layer MLA may be formed as a micro lens array disposed in the emission areas EA1, EA2, and EA3 of the display area DA.

In an embodiment, the lens LS may have a size corresponding to the emission area of each pixel PX, and may overlap (e.g., completely overlap) the light emitting element LE disposed in each pixel PX. As an example, the lens LS may be a micro lens having a size corresponding to a size of each of the light emitting elements LE. In an embodiment, the lens LS may cover the light emitting element LE and the periphery of the light emitting element LE and may have a greater size than each light emitting element LE in plan view. In an embodiment, the lens LS may be a micro lens having a shape of a convex lens provided above the light emitting elements LE, but a type, a shape, and/or a size of the lens LS are not limited thereto.

The lens LS may be made of a transparent material so that light incident from the light emitting elements LE may be transmitted. The lens LS may be made of a material and/or be formed in a shape suitable for appropriately controlling or improving characteristics of light emitted from the pixels PX.

In an embodiment, the display panel 100 or the display device 10 including the display panel 100 may further include an additional component. As an example, the display panel 100 or the display device 10 including the display panel 100 may further include light conversion layers, color filters, or the like, disposed above the pixels PX (or the light emitting elements LE).

As described above, the display device 10 according to embodiments may include the backplane BPL including the first backplane layer GBP including the first substrate GSUB and the switching transistor SWT and the second backplane layer SBP including the second substrate SSUB and the driving transistor DRT. In embodiments, the switching transistor SWT and the driving transistor DRT may be different types or structures of transistors. For example, the switching transistor SWT may be a TFT formed on an insulating substrate such as a glass substrate or a flexible substrate, and the driving transistor DRT may be a MOSFET (e.g., a MOSFEET formed by a silicon semiconductor process) formed on a semiconductor substrate such as a silicon wafer.

According to embodiments, by forming the switching transistor SWT and the driving transistor DRT separately in the first backplane layer GBP and the second backplane layer SBP, respectively, it is possible to reduce a degree of integration of the backplane BPL and readily manufacture a high-resolution display device 10.

In some embodiments, by forming the driving transistor DRT as the MOSFET, it is possible to reduce power consumption of the display device 10. For example, by forming the driving transistors DRT of the pixels PX occupying about 20% to about 30% of the total power consumption of the display device 10 as the MOSFETs, it is possible to significantly reduce the power consumption of the display device 10.

In some embodiments, by forming the switching transistors SWT of the pixels PX as the TFTs, it is possible to readily form various types of pixel circuits PXC. For example, the switching transistors SWT included in the pixel circuit PXC may be readily disposed or formed on the first substrate GSUB without an additional cost due to a change in structure of the pixel circuit PXC.

The display device 10 according to one embodiment of the disclosure can be applied to various electronic devices. The electronic device according to the embodiment of the disclosure includes the display device 10 described above, and may further include modules or devices having additional functions in addition to the display device 10.

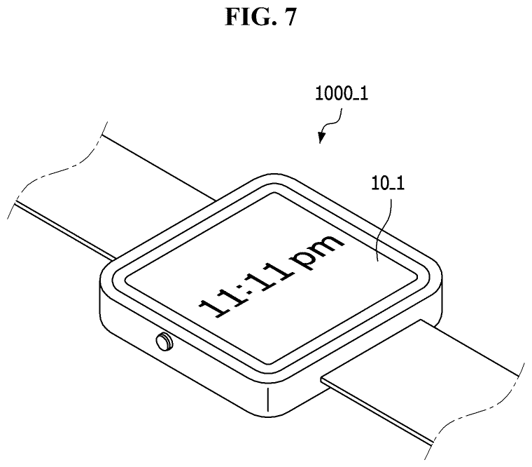

FIG. 7 is a schematic view illustrating a smart watch including the display device according to an embodiment.

Referring to FIG. 7, a display device 10_1 according to an embodiment may be applied to a smart watch 1000_1, which is one of smart devices. In an embodiment, the display device 10_1 may be the display device 10 described with reference to FIGS. 1 to 6.

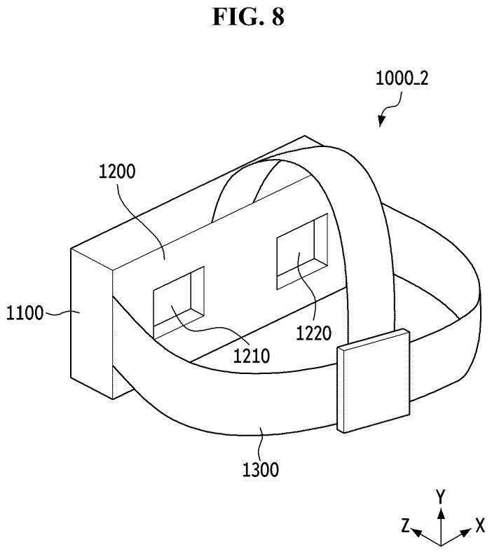

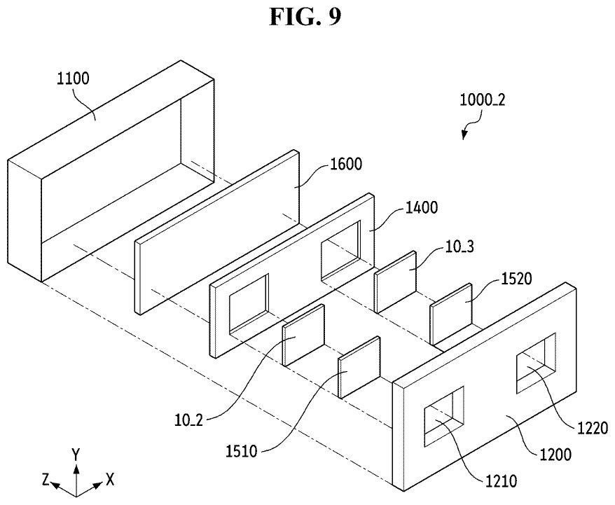

FIGS. 8 and 9 are schematic views illustrating a head mounted display device including the display device according to an embodiment.

Referring to FIGS. 8 and 9, a head mounted display device 1000_2 according to an embodiment may be a virtual reality device. The head mounted display device 1000_2 may include a first display device 10_2, a second display device 10_3, a display device housing portion 1100, a housing portion cover 1200, a first eyepiece 1210, a second eyepiece 1220, a head mounted band 1300, a middle frame 1400, a first optical member 1510, a second optical member 1520, and a control circuit board 1600.

The first display device 10_2 may display an image to a user's left eye, and the second display device 10_3 may display an image to a user's right eye. In an embodiment, each of the first display device 10_2 and the second display device 10_3 may be the display device 10 described with reference to FIGS. 1 to 6.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and disposed between the second display device 10_3 and the control circuit board 1600. The middle frame 1400 may support and fix the first display device 10_2, the second display device 10_3, and the control circuit board 1600.

The control circuit board 1600 may be disposed between the middle frame 1400 and the display device housing portion 1100. The control circuit board 1600 may be connected to the first display device 10_2 and the second display device 10_3 through a connector. The control circuit board 1600 may convert an image source input from the outside into video data, and transmit the video data to the first display device 10_2 and the second display device 10_3 through the connector.

The control circuit board 1600 may transmit video data corresponding to a left eye image optimized for the user's left eye to the first display device 10_2 and transmit video data corresponding to a right eye image optimized for the user's right eye to the second display device 10_3. In another example, the control circuit board 1600 may transmit the same video data to the first display device 10_2 and the second display device 10_3.

The display device housing portion 1100 may accommodate the first display device 10_2, the second display device 10_3, the middle frame 1400, the first optical member 1510, the second optical member 1520, and the control circuit board 1600. The housing portion cover 1200 may cover an opened surface of the display device housing portion 1100. The housing portion cover 1200 may include the first eyepiece 1210 on which the user's left eye is disposed and the second eyepiece 1220 on which the user's right eye is disposed. It has been illustrated in FIGS. 8 and 9 that the first eyepiece 1210 and the second eyepiece 1220 are separately disposed, but embodiments are not limited thereto. The first eyepiece 1210 and the second eyepiece 1220 may be merged as an eyepiece.

The first eyepiece 1210 may be aligned with the first display device 10_2 and the first optical member 1510, and the second eyepiece 1220 may be aligned with the second display device 10_3 and the second optical member 1520. Accordingly, a user may view a magnified virtual image of the first display device 10_2 through the first optical member 1510 and the first eyepiece 1210, and may view a magnified image of the second display device 10_3 through the second optical member 1520 and the second eyepiece 1220.

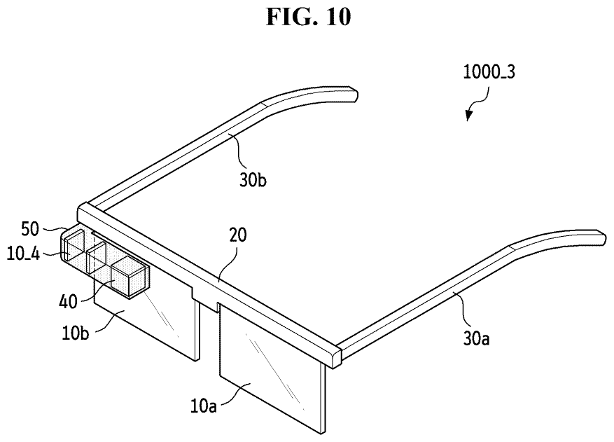

The head mounted band 1300 may fix the display device housing portion 1100 to a user's head so that the first eyepiece 1210 and the second eyepiece 1220 of the housing portion cover 1200 may be maintained in a state where they are disposed on the user's left eye and right eye, respectively. In case that the display device housing portion 1100 is implemented to have a light weight and a small size, the head mounted display device 1000_2 may include an eyeglass frame as illustrated in FIG. 10 instead of the head mounted band 1300.

For example, the head mounted display device 1000_2 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 10 is a schematic view illustrating a head mounted display device including the display device according to an embodiment.

Referring to FIG. 10, a head mounted display device 1000_3 according to an embodiment may be an eyeglasses-type device. The head mounted display device 1000_3 according to an embodiment may include a display device 10_4, a left eye lens 10a, a right eye lens 10b, a support frame 20, eyeglass frame legs 30a and 30b, a reflective member 40, and a display device housing portion 50.

It has been illustrated in FIG. 10 that the head mounted display device 1000_3 is an eyeglasses-type display device including the eyeglasses frame legs 30a and 30b, but embodiments are not limited thereto. For example, the head mounted display device 1000_3 may be applied in various forms in other electronic devices.

The display device housing portion 50 may include the display device 10_4 and the reflective member 40 (or a light path conversion member). An image displayed on the display device 10_4 may be reflected by the reflective member 40 and provided to a user's right eye through the right eye lens 10b. For example, a user may view an augmented reality image in which a virtual image displayed on the display device 10_4 through his/her right eye and a real image seen through the right eye lens 10b are combined with each other. In an embodiment, the display device housing portion 50 may include an optical member disposed between the display device 10_4 and the reflective member 40. An image displayed on the display device 10_4 may be magnified by the optical member, converted in an optical path by the reflective member 40, and provided to the user's right eye through the right eye lens 10b.

It has been illustrated in FIG. 10 that the display device housing portion 50 is disposed at a right end portion of the support frame 20, but embodiments are not limited thereto. For example, the display device housing portion 50 may be disposed at a left end portion of the support frame 20. For example, an image displayed on the display device 10_4 may be reflected by the reflective member 40 and provided to a user's left eye through the left eye lens 10a. For example, the user may view an image displayed on the display device 10_4 through his/her left eye. In another example, the display device housing portions 50 may be disposed at the left and right end portions of the support frame 20. For example, the user may view an image displayed on the display device 10_4 through his/her left and right eyes. In an embodiment, the display device 10_4 may be the display device 10 described with reference to FIGS. 1 to 6.

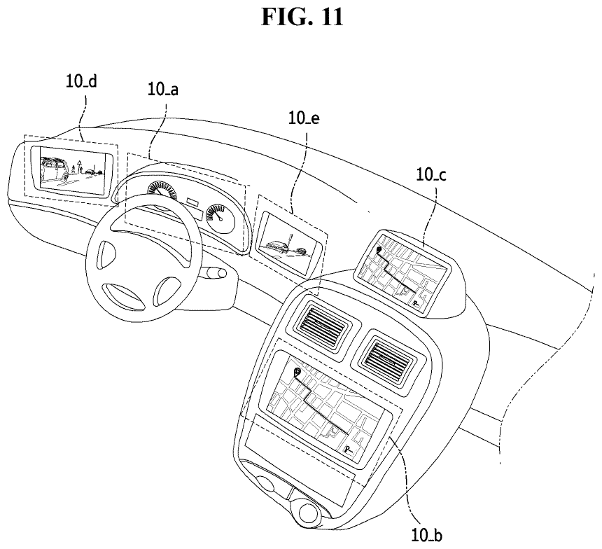

FIG. 11 is a schematic view illustrating an instrument board and a center fascia of a vehicle including the display devices according to an embodiment. A vehicle to which display devices 10_a, 10_b, 10_c, 10_d, and 10_e according to an embodiment are applied is illustrated in FIG. 11.

Referring to FIG. 11, the display devices 10_a, 10_b, and 10_c according to an embodiment may be applied to an instrument board of the vehicle, applied to a center fascia of the vehicle, or applied to a center information display (CID) disposed on a dashboard of the vehicle. For example, the display devices 10_d and 10_e according to an embodiment may be applied to a room mirror display substituting for a side-view mirror of the vehicle. In an embodiment, at least one of the display devices 10_a, 10_b, 10_c, 10_d, and 10_e may be the display device 10 described with reference to FIGS. 1 to 6.

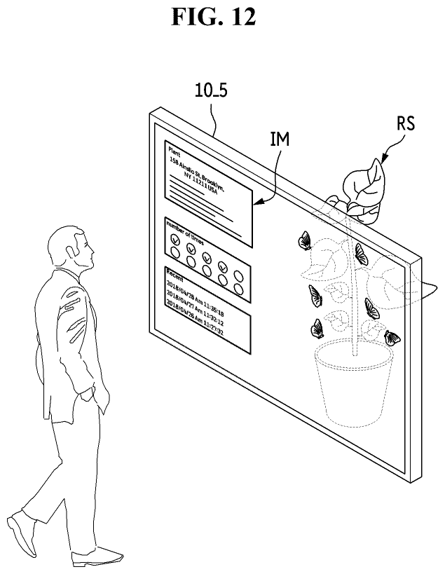

FIG. 12 is a schematic view illustrating a transparent display device including the display device according to an embodiment.

Referring to FIG. 12, a display device 10_5 according to an embodiment may be applied to a transparent display device. The transparent display device may transmit light while displaying an image IM. Therefore, a user positioned on a front surface of the transparent display device may not only view the image IM displayed on the display device 10_5, but also see an object RS or a background positioned on a rear surface of the transparent display device. In case that the display device 10_5 is applied to the transparent display device, a substrate of the display device 10_5 may include a light transmitting portion capable of transmitting light or may be made of a material capable of transmitting light. In an embodiment, the display device 10_5 may be the display device 10 described with reference to FIGS. 1 to 6.

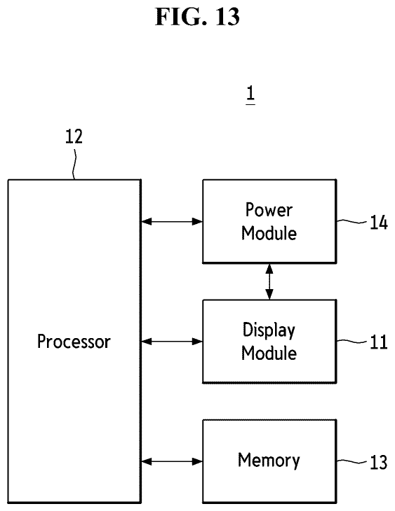

FIG. 13 is a block diagram of an electronic device according to one embodiment of the disclosure.

Referring to FIG. 13, the electronic device 1 according to one embodiment of the disclosure may include a display module 11, a processor 12, a memory 13, and a power module 14.

The display module 11 may include a display panel for displaying an image. For example, the display module 11 may include the display panel 100 according to at least one of the embodiments described above.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. The processor 12 may transmit an image data signal and/or an input control signal stored in the memory 13 to the display module 11. For example, the processor 12 executes an application stored in the memory 13, the image data signal and/or the input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 1 according to the one embodiment of the disclosure may be included in the display device 10 according to the embodiments of the disclosure. Some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices in the electronic device 1 other than the display device 10.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation.

What is claimed is:

1. A display device comprising:
a backplane including:
a first backplane layer including a first substrate and a switching transistor disposed on the first substrate, and
a second backplane layer including a second substrate and a driving transistor disposed on the second substrate; and
a light emitting element layer disposed on the backplane and including a light emitting element electrically connected to the driving transistor.

2. The display device of claim 1, wherein
the switching transistor is a thin film transistor formed on the first substrate, and
the driving transistor is a metal oxide semiconductor field effect transistor formed on the second substrate.

3. The display device of claim 1, wherein the first substrate and the second substrate are made of different materials.

4. The display device of claim 3, wherein the first substrate is an insulating substrate, and the second substrate is a semiconductor substrate.

5. The display device of claim 1, wherein the first backplane layer further includes a capacitor disposed on the first substrate.

6. The display device of claim 1, wherein
the first backplane layer further includes a connection electrode disposed on the first substrate and electrically connected to the switching transistor, and
the connection electrode is exposed on an upper surface of the first backplane layer.

7. The display device of claim 6, wherein the second backplane layer further includes a first contact terminal and a second contact terminal disposed on the second substrate and electrically connected to a source region and a drain region of the driving transistor, respectively.

8. The display device of claim 7, wherein
the second backplane layer is disposed on the first backplane layer, and
the light emitting element layer is disposed on the second backplane layer.

9. The display device of claim 8, wherein
one of the first contact terminal and the second contact terminal is electrically connected to the connection electrode, and
the other of the first contact terminal and the second contact terminal is electrically connected to the light emitting element.

10. The display device of claim 1, wherein
the backplane further includes a line layer disposed between the second backplane layer and the light emitting element layer, and
the line layer includes conductive patterns electrically connecting the driving transistor to the light emitting element and the switching transistor.

11. The display device of claim 1, wherein
the light emitting element layer further includes a pixel electrode disposed on the backplane and electrically connected to the driving transistor, and
the light emitting element is disposed on the pixel electrode.

12. The display device of claim 11, wherein the light emitting element is connected to the pixel electrode.

13. The display device of claim 11, wherein the light emitting element is a micro light emitting diode including a first semiconductor layer, a light emitting layer, and a second semiconductor layer that are sequentially disposed on the pixel electrode.

14. The display device of claim 11, further comprising:
a pixel including the switching transistor, the driving transistor, and the light emitting element,
wherein the light emitting element layer further includes a common electrode disposed on the light emitting element.

15. A display device comprising:
a first backplane layer including an insulating substrate and a thin film transistor formed on the insulating substrate;
a second backplane layer disposed on the first backplane layer and including a semiconductor substrate and a metal oxide semiconductor field effect transistor formed on the semiconductor substrate; and
a light emitting element layer disposed on the second backplane layer and including a light emitting element.

16. The display device of claim 15, wherein the first backplane layer further includes a connection electrode electrically connected between the thin film transistor and the metal oxide semiconductor field effect transistor.

17. The display device of claim 15, further comprising:
a line layer disposed between the second backplane layer and the light emitting element layer,
wherein the line layer includes a conductive pattern electrically connected between the metal oxide semiconductor field effect transistor and the light emitting element.

18. The display device of claim 17, wherein the light emitting element layer further includes a pixel electrode disposed on the line layer, and
the light emitting element is disposed on the pixel electrode.

19. The display device of claim 15, further comprising:
a pixel including the thin film transistor, the metal oxide semiconductor field effect transistor, and the light emitting element,
wherein the thin film transistor is a switching transistor of the pixel, and
the metal oxide semiconductor field effect transistor is a driving transistor of the pixel.

20. An electronic device comprising:
a display module including a display panel; and
a processor that transmits an image data signal to the display module, wherein the display panel comprising:
a backplane including:
a first backplane layer including a first substrate and a switching transistor disposed on the first substrate, and
a second backplane layer including a second substrate and a driving transistor disposed on the second substrate; and
a light emitting element layer disposed on the backplane and including a light emitting element electrically connected to the driving transistor.
